(19) United States
(12) Patent Application Publication
(10) Pub. No.: US 2025/0159961 A1
(43) Pub. Date: May 15, 2025

(54) SEMICONDUCTOR DEVICE

(71) Applicant: FUJI ELECTRIC CO., LTD., Kawasaki-shi (JP)

(72) Inventor: Naoki KUMAGAI, Matsumoto-city (JP)

(73) Assignee: FUJI ELECTRIC CO., LTD., Kawasaki-shi (JP)

(21) Appl. No.: 18/902,023

(22) Filed: Sep. 30, 2024

(30) Foreign Application Priority Data
Nov. 15, 2023 (JP) 2023-194676

(51) Int. Cl. H01L 29/417; H01L 29/45; H01L 29/78

(52) U.S. Cl. CPC H10D 64/252; H10D 62/83; H10D 64/62; H10D 64/647; H10D 84/141

(57) ABSTRACT

A semiconductor device includes, on a semiconductor substrate of a first conductivity type, an active region through which a main current flows, a terminal region surrounding a periphery of the active region, and an intermediate region between the active region and the terminal region. The semiconductor device has, in the active region, a front electrode disposed on a first main surface of the semiconductor substrate and connected to a first semiconductor region of a second conductivity type. In the intermediate region, the semiconductor device has a source ring electrically connected to the front electrode and to a second semiconductor region of the second conductivity type for extracting hole current. A contact between the front electrode in the active region and the first semiconductor region is an ohmic contact. A contact between the source ring in the intermediate region and the second semiconductor region includes a Schottky junction or a heterojunction.

### CROSS REFERENCE TO RELATED APPLICATIONS

This application is based upon and claims the benefit of priority of the prior Japanese Patent Application No. 2023-194676, filed on Nov. 15, 2023, the entire contents of which are incorporated herein by reference.

### BACKGROUND OF THE INVENTION

### 1. Field of the Invention

Embodiments of the invention relate to a semiconductor device.

### 2. Description of the Related Art

Conventionally, a semiconductor device is known in which a source ring portion connected to a source potential is disposed in a p-type region between an active region and a non-operating region such as a voltage withstanding structure for extracting hole current around the active region (refer to, for example, Japanese Laid-Open Patent Publication No. 2021-44274).

### SUMMARY OF THE INVENTION

According to an embodiment of the present disclosure, a semiconductor device includes: a semiconductor substrate of a first conductivity type, the semiconductor substrate having an active region through which a main current flows, a terminal region surrounding a periphery of the active region in a top view of the semiconductor substrate, and an intermediate region between the active region and the terminal region, the semiconductor substrate having a first main surface and a second main surface opposite to each other; the semiconductor device further including: a front electrode provided in the active region, on the first main surface of the semiconductor substrate; a first semiconductor region of a second conductivity type formed in the semiconductor substrate, and being connected to the front electrode; a second semiconductor region of the second conductivity type formed in the semiconductor substrate, for extracting hole current; and a source ring provided in the intermediate region, the source ring being electrically connected to the front electrode and connected to the second semiconductor region. A contact between the front electrode in the active region and the first semiconductor region is an ohmic contact. A contact between the source ring in the intermediate region and the second semiconductor region includes a Schottky junction or a heterojunction.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view depicting a structure of a silicon carbide semiconductor device according to a first embodiment.

FIG. 2 is a cross-sectional view depicting the structure of the silicon carbide semiconductor device according to the first embodiment, along cutting line X-X′ in FIG. 1.

FIG. 3 is a cross-sectional view depicting the structure of the silicon carbide semiconductor device according to the first embodiment, along cutting line Y-Y′ in FIG. 1.

FIG. 4 is a cross-sectional view depicting a first structure of a source ring of the silicon carbide semiconductor device according to the first embodiment.

FIG. 5 is a band diagram, during forward bias (positive voltage at drain), in the first structure of the source ring of the silicon carbide semiconductor device according to the first embodiment.

FIG. 6 is a band diagram, at thermal equilibrium (drain is 0V), in the first structure of the source ring of the silicon carbide semiconductor device according to the first embodiment.

FIG. 7 is a band diagram during reverse bias (negative voltage at drain) of the first structure of the source ring of the silicon carbide semiconductor device according to the first embodiment.

FIG. 8 is a cross-sectional view depicting a second structure of the source ring of the silicon carbide semiconductor device according to the first embodiment.

FIG. 9 is a band diagram during forward bias (positive voltage at drain) in the second structure (n⁺-type) of the source ring of the silicon carbide semiconductor device according to the first embodiment.

FIG. 10 is a band diagram, at thermal equilibrium (0V at drain) in the second structure (n⁺-type) of the source ring of the silicon carbide semiconductor device according to the first embodiment.

FIG. 11 is a band diagram, during reverse bias (negative voltage at drain), in the second structure (n⁺-type) of the source ring of the silicon carbide semiconductor device according to the first embodiment.

FIG. 12 is a band diagram, during forward bias (positive voltage at drain), in the second structure (p⁺-type) of the source ring of the silicon carbide semiconductor device according to the first embodiment.

FIG. 13 is a band diagram, at thermal equilibrium (0V at drain), in the second structure (p⁺-type) of the source ring of the silicon carbide semiconductor device according to the first embodiment.

FIG. 14 is a band diagram, during reverse bias (negative voltage at drain), in the second structure (p⁺-type) of the source ring of the silicon carbide semiconductor device according to the first embodiment.

FIG. 15 is a top view depicting a structure of the silicon carbide semiconductor device according to a second embodiment.

FIG. 16 is a cross-sectional view depicting a first structure of the source ring in the silicon carbide semiconductor device according to the second embodiment, along cutting line Y-Y′ in FIG. 15.

FIG. 17 is a top view of regions S of the first structure of the source ring in the silicon carbide semiconductor device according to the second embodiment.

FIG. 18 is a cross-sectional view depicting a second structure of the source ring of the silicon carbide semiconductor device according to the second embodiment, along cutting line Y-Y′ in FIG. 15.

FIG. 19 is a top view depicting the regions S of the second structure of the source ring of the silicon carbide semiconductor device according to the second embodiment.

FIG. 20 is a cross-sectional view depicting a first structure of the source ring of the silicon carbide semiconductor device according to a third embodiment.

FIG. 21 is a cross-sectional view depicting a second structure of the source ring of the silicon carbide semiconductor device according to the third embodiment.

FIG. 22 is the top view depicting the second structure of the source ring of the silicon carbide semiconductor device according to the third embodiment.

FIG. 23 is a cross-sectional view depicting a first structure of the source ring of the silicon carbide semiconductor device according to a fourth embodiment.

FIG. 24 is a cross-sectional view depicting a second structure of the source ring of the silicon carbide semiconductor device according to the fourth embodiment.

FIG. 25 is a top view depicting the second structure of the source ring of the silicon carbide semiconductor device according to the fourth embodiment.

FIG. 26 is a top view depicting a structure of the silicon carbide semiconductor device of an example.

FIG. 27 is a graph depicting light emission intensity distribution from a surface along cutting line Y-Y′ during reverse conduction (parasitic diode energization) of an existing silicon carbide semiconductor device.

FIG. 28 is a graph depicting the light emission intensity distribution from the surface along cutting line Y-Y′ during reverse conduction (parasitic diode energization) in the first structure of the source ring of the silicon carbide semiconductor device according to the third embodiment.

FIG. 29 is a cross-sectional view depicting a structure of a source ring portion of a conventional silicon carbide semiconductor device.

FIG. 30 is a band diagram of the source ring of the conventional silicon carbide semiconductor device.

### DETAILED DESCRIPTION OF THE INVENTION

First, problems associated with the conventional techniques are discussed. In a conventional semiconductor device, when a MOSFET parasitic diode is used as a freewheeling diode, current concentrates in the source ring portion thereby increasing the hole density, whereby a problem occurs in that on-voltage tends to easily rise due to the growth of stacking faults starting from directly below the source ring portion. The present disclosure provides a semiconductor device that may suppress current concentration at the source ring portion and hinder the growth of stacking faults.

In light of the problems above, a semiconductor device according to the present disclosure has the following features. The semiconductor device includes, on a semiconductor substrate of a first conductivity type, an active region through which a main current flows, a terminal region surrounding a periphery of the active region, and an intermediate region between the active region and the termination region. The semiconductor device has, on a first main surface of the semiconductor substrate in the active region, a front electrode connected to a first semiconductor region of a second conductivity type, and in the intermediate region, the semiconductor device has a source ring electrically connected to the front electrode and connected to a second semiconductor region of the second conductivity type for extracting hole current. A contact between the front electrode in the active region and the first semiconductor region is an ohmic contact and a contact between the source ring in the intermediate region and the second semiconductor region is a Schottky junction.

According to the present disclosure above, by forming the contact between the source ring and the p-type base layer as a Schottky junction, the holes may be sufficiently extracted from the p-type base layer in the source ring when dV/dt is applied and the injection of holes from the source ring is prevented when a parasitic diode of the MOSFET is forward biased. Accordingly, the concentration of current in the source ring may be suppressed to thereby hinder the growth of stacking faults while ensuring dV/dt capability.

In the semiconductor device according to the present disclosure above, the contact between the source ring in the intermediate region and the second semiconductor region is a heterojunction containing a semiconductor having a large band offset on the valence band side relative to the second semiconductor region.

In the semiconductor device according to the present disclosure is, in the present disclosure above, the semiconductor having a large band offset on the valence band side relative to the second semiconductor region is silicon.

In light of the problems above, a semiconductor device according to the present disclosure has the following features. The semiconductor device includes, on the semiconductor substrate of the first conductivity type, an active region through which a main current flows, a terminal region surrounding the periphery of the active region, and an intermediate region between the active region and the termination region. The semiconductor device includes, in the active region, a front electrode connected to the first semiconductor region of the second conductivity type, on the first main surface of the semiconductor substrate and in the intermediate region, has a source ring electrically connected to the front electrode and connected to the second semiconductor region of the second conductivity type, for extracting hole current. A diode is disposed between the front electrode and the source ring, which allows a current to flow from the source ring to the front electrode and blocks a current flowing in the opposite direction.

According to the present disclosure above, when dV/dt is applied, holes may be extracted from the p-type base layer in the source ring, and when the parasitic diode of the MOSFET is forward biased, the diode may mitigate the injection of holes from the source ring. Thus, current concentration in the source ring may be suppressed to thereby hinder the growth of stacking faults while ensuring dV/dt capability.

In the semiconductor device according to the present disclosure, in the present disclosure above, the diode is formed by a polysilicon layer formed on the semiconductor substrate via an insulating layer.

In the semiconductor device according to the present disclosure, instead of the diode, a resistor is disposed between the front electrode and the source ring.

In the semiconductor device according to the present disclosure, in the present disclosure above, the resistor is formed by a polysilicon layer formed on the semiconductor substrate via an insulating layer.

In light of the problems above, a semiconductor device according to the present disclosure has the following features. The semiconductor device includes, on the semiconductor substrate of the first conductivity type, an active region through which a main current flows, a terminal region surrounding the periphery of the active region, and an intermediate region between the active region and the termination region. The semiconductor device has, in the active region, the front electrode connected to the first semiconductor region of the second conductivity type, on the first main surface of the semiconductor substrate, and in the intermediate region, has the source ring electrically connected to the front electrode and connected to the second semiconductor region of the second conductivity type, for extracting hole current. A contact resistance between the source ring and the second semiconductor region is greater than a contact resistance between the front electrode and the first semiconductor region in the active region.

According to the present disclosure above, when dV/dt is applied, the holes may be extracted from the p-type base layer in the source ring, and when the parasitic diode of the MOSFET is forward biased, the injection of holes from the source ring may be mitigated. Therefore, the concentration of current in the source ring may be suppressed to thereby hinder the growth of stacking faults while ensuring dV/dt capability.

In the semiconductor device according to the present disclosure, in the present disclosure above, an average area of a region in which the source ring and the second semiconductor region are in ohmic contact is smaller than an average area of a region in which the front electrode and the first semiconductor region in the active region are in ohmic contact.

In the semiconductor device according to the present disclosure, in the present disclosure above, the first semiconductor region in the active region has an impurity concentration higher than an impurity concentration of the second semiconductor region in the intermediate region.

In the semiconductor device according to the present disclosure, in the present disclosure above, the first semiconductor region in the active region is apart from the second semiconductor region connected to the source ring of the intermediate region.

Here, problems associated with conventional semiconductor devices are discussed. From the viewpoint of power semiconductor devices, semiconductor materials to replace silicon have been considered and silicon carbide (SiC) has attracted attention as a semiconductor material capable of fabricating (manufacturing) next-generation power semiconductor devices superior in terms of low on-voltage, high-speed characteristics, and high-temperature characteristics.

The energy level of p-type impurities is deep in SiC, so the resistance of a p-type region is high, especially at low temperatures such as −40 degrees C. or −55 degrees C. Thus, when dV/dt is applied to a device, a lateral voltage drop due to hole current flowing in the p-type region is large, and a large voltage is applied between the p-type region and an electrode disposed thereon via an insulating film, resulting in a problem that the insulating film is destroyed. This phenomenon is likely to occur near the active region where current from non-active regions such as a voltage withstanding structure concentrates. To solve this, a source ring portion is conventionally disposed to lead out the hole current from the periphery of the active region to a source electrode.

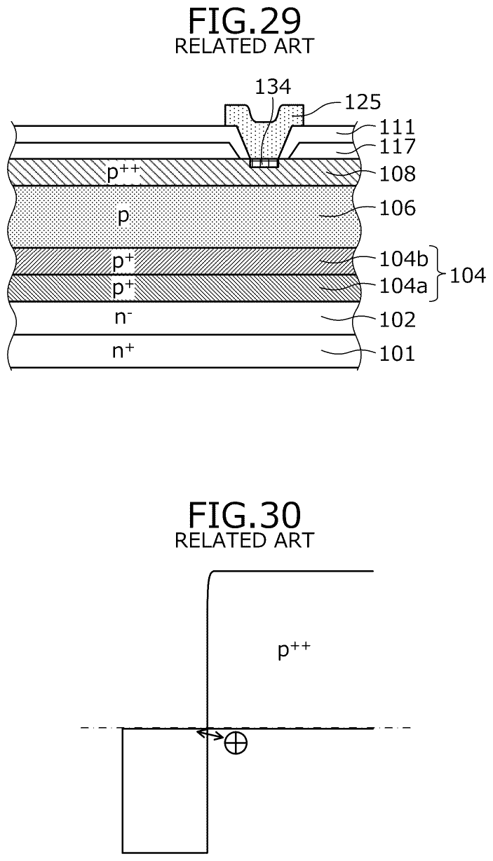

FIG. 29 is a cross-sectional view depicting a structure of a source ring portion of a conventional silicon carbide semiconductor device. A left side of FIG. 29 is an active region 40 side and the right side of FIG. 29 is a terminal structure region 42 side. In the conventional silicon carbide semiconductor device, an n⁻-type drift layer 102, a first p⁺-type region 104a, a second p⁺-type region 104b, a p-type base layer 106, and a p⁺⁺-type contact region 108 are deposited on an n⁺-type silicon carbide substrate 101. An initial oxide film 117 and an interlayer insulating film 111 are disposed on the front surface of the p⁺⁺-type contact region 108, source rings 125 are imbedded in openings of the initial oxide film 117 and the interlayer insulating film 111, and a silicide layer 134 of the source ring 125 is in ohmic contact with the p⁺⁺-type contact region 108. The source ring 125 is electrically connected to the source electrode (not depicted). This configuration allows hole current from a peripheral portion of the active region to be extracted and to flow to the source electrode.

FIG. 30 is a band diagram of the source ring of the conventional silicon carbide semiconductor device. FIG. 30 depicts a band gap of the p⁺⁺-type contact region 108. In FIG. 30, a dashed line depicts the Fermi level (level), and a symbol with + surrounded by a circle depicts a hole. The same is true for other band diagrams other than FIG. 30. Since the energy level of the valence band of the p⁺⁺-type contact region 108 is nearly equal to the energy level of the valence band of an ohmic electrode (silicide layer 134), holes can be extracted from the p⁺⁺-type contact region 108 to the ohmic electrode, but holes can also be injected from the p⁺⁺-type contact region 108 to the n⁻-type drift layer 102.

Then, when a parasitic diode is used as a freewheeling diode for the silicon carbide semiconductor device disposed with the source ring 125, current concentrates in the source ring 125 and the hole density increases, whereby a problem occurs in that the on-voltage tends to increase due to the growth of stacking faults originating from directly beneath the source ring 125.

Embodiments of a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

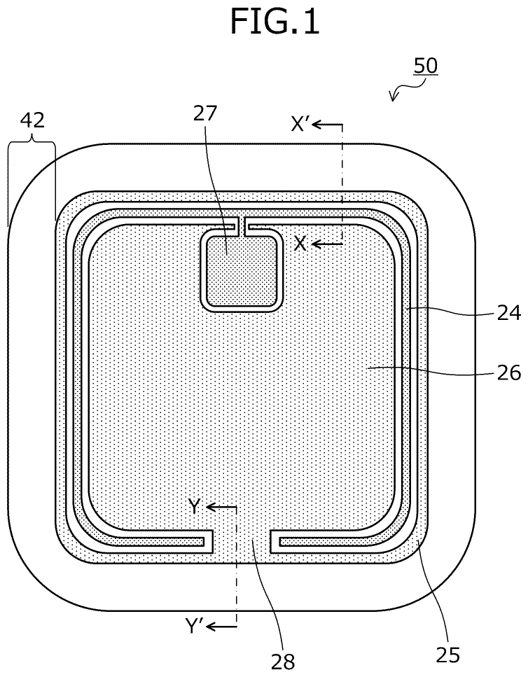

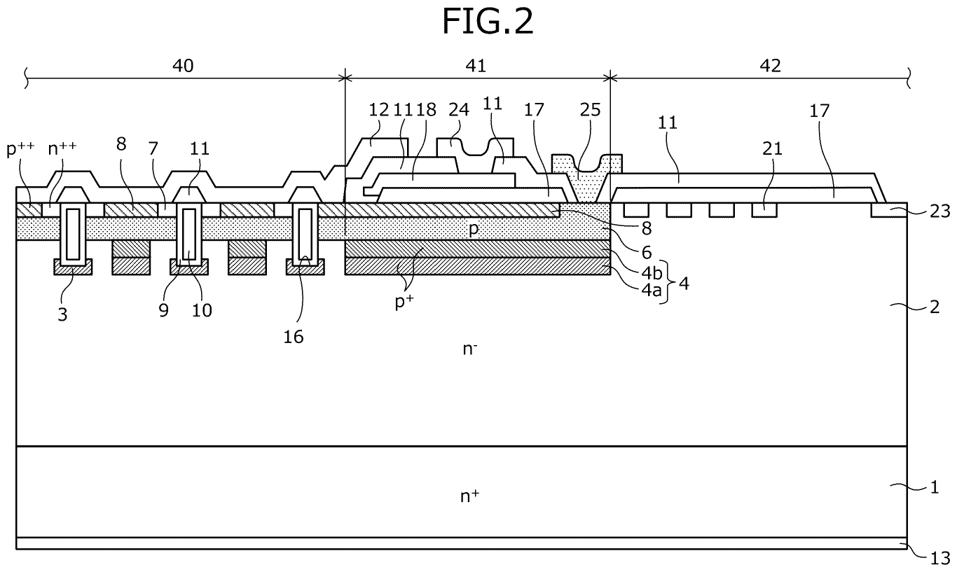

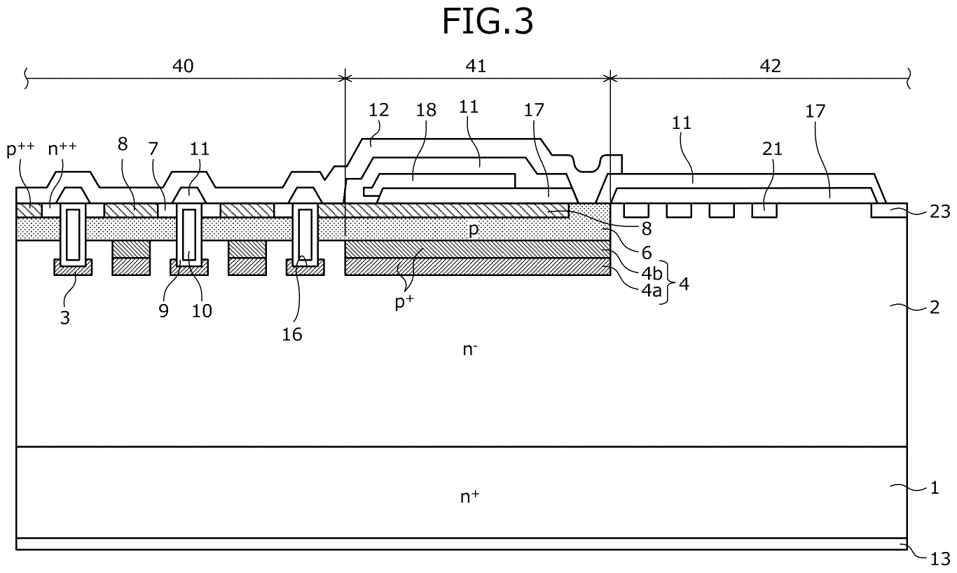

A semiconductor device according to the present disclosure is configured using a wide band gap semiconductor. In a first embodiment, a trench-type MOSFET 50 is described as an example of a silicon carbide semiconductor device fabricated (manufactured) using, for example, silicon carbide (SiC) as the wide band gap semiconductor. FIG. 1 is a top view depicting a structure of the silicon carbide semiconductor device according to the first embodiment. FIG. 2 is a cross-sectional view depicting the structure of the silicon carbide semiconductor device according to the first embodiment, along cutting line X-X′ in FIG. 1. FIG. 3 is a cross-sectional view depicting the structure of the silicon carbide semiconductor device according to the first embodiment, along cutting line Y-Y′ in FIG. 1.

As depicted in FIGS. 1 to 3, a trench MOSFET 50 according to the first embodiment includes an active region 40 in which a device structure is formed and through which a current flows when the device is in an on-state, a terminal structure region 42 that surrounds a periphery of the active region 40 and maintains a breakdown voltage, and an intermediate region 41 provided between the active region 40 and the terminal structure region 42. In the trench MOSFET 50, an n⁻-type drift layer 2 is deposited on a first main surface (front surface), for example, a (0001) surface (Si surface), of an n⁺-type silicon carbide substrate 1.

The n⁺-type silicon carbide substrate 1 is a silicon carbide single crystal substrate. An n⁻-type drift layer 2 has an impurity concentration that is lower than an impurity concentration of the n⁺-type silicon carbide substrate 1, and the n⁻-type drift layer 2 constitutes, for example, a low concentration n-type drift layer. An n-type high concentration region (not depicted) may be disposed on a first surface of the n⁻-type drift layer 2, opposite to a second surface thereof facing the n⁺-type silicon carbide substrate 1. The n-type high concentration region is a high concentration n-type layer having an impurity concentration lower than the impurity concentration of the n⁺-type silicon carbide substrate 1 and higher than the impurity concentration of the n⁻-type drift layer 2.

A p-type base layer (a second semiconductor region of a second conductivity type) 6 is disposed on a first surface of the n-type drift layer 2 (or the n-type high concentration region when the n-type high concentration region is disposed), opposite to the second surface thereof facing the n⁺-type silicon carbide substrate 1. Hereinafter, the n⁺-type silicon carbide substrate 1, the n⁻-type drift layer 2, and the p-type base layer 6 are collectively referred to as a silicon carbide semiconductor substrate. In the p-type base layer 6, n⁺⁺-type source regions 7 and p⁺⁺-type contact regions (first semiconductor regions of the second conductivity type) 8 are selectively disposed.

A drain electrode serving as a back electrode 13 is disposed on a second main surface (back surface, i.e., a back surface of the silicon carbide semiconductor substrate) of the n⁺-type silicon carbide substrate 1.

A trench structure is formed in the silicon carbide semiconductor substrate, at the first main surface (surface having the p-type base layer 6) thereof. Specifically, trenches 16 penetrate through the p-type base layer 6 from a first surface of the p-type base layer 6 (the first main surface of the silicon carbide semiconductor substrate), opposite to a second surface thereof facing the n⁺-type silicon carbide substrate 1, the trenches 16 reaching the n⁻-type drift layer 2. The trenches 16 are disposed in a striped pattern. Along inner walls of the trenches 16, gate insulating films 9 are formed on bottoms and side walls of the trenches 16 and gate electrodes 10 are formed on the gate insulating films 9 in the trenches 16. The gate electrodes 10 are insulated from the n⁻-type drift layer 2 and the p-type base layer 6 by the gate insulating films 9. A part of each of the gate electrodes 10 may protrude toward a later-described source electrode 12, from an upper side (side facing the source electrode 12 described later) of the trench 16 thereof.

A second p⁺-type base region 4 is selectively disposed on the first surface of the n⁻-type drift layer 2 (the first main surface side of the silicon carbide semiconductor substrate). The second p⁺-type base region 4 is disposed in the n⁻-type drift layer 2 at least at the first surface thereof. The second p⁺-type base region 4 is apart from the trenches 16 and reaches a deep position closer to the n⁺-type silicon carbide substrate 1 than are the bottoms of the trenches 16. The second p⁺-type region 4 is configured by a first p⁺-type region 4a having the same thickness as first p⁺-type base regions 3 described below and a second p⁺-type region 4b disposed on the surface of the first p⁺-type region 4a.

The first p⁺-type base regions 3 are disposed at positions facing the bottoms of the trenches 16 in the depth direction. A width of each of the first p⁺-type base regions 3 is the same as or wider than a width of each of the trenches 16. The bottoms of the trenches 16 may reach the first p⁺-type base regions 3 or may be located in the n⁻-type drift layer 2 between the p-type base layer 6 and the first p⁺-type base regions 3. The first p⁺-type base regions 3 and the second p⁺-type base region 4 are doped with, for example, aluminum (Al).

A portion of the first p⁺-type base regions 3 extends toward the trenches 16 to be connected to the second p⁺-type base region 4. The first p⁺-type region 4a of the second p⁺-type base region 4 is closer to the n⁺-type silicon carbide substrate 1 than are the bottoms of the trenches 16 and a portion thereof extends to be connected to the first p⁺-type base regions 3. The second p⁺-type region 4b of the second p⁺-type base region 4 is closer to the source electrode 10 than are the bottoms of the trenches 16 and a portion thereof may be extended. FIGS. 2 and 3 depict a location where the first p⁺-type base regions 3 and the second p⁺-type base region 4 are arranged apart from each other. The p-type base layer 6 is disposed in the active region 40 and the intermediate region 41 so as to cover the second p⁺-type region 4b and the n⁻-type drift layer 2.

The interlayer insulating film 11 is disposed in an entire area of the front surface of the silicon carbide semiconductor substrate so as to cover the gate electrodes 10 embedded in the trenches 16. The source electrode (front electrode) 12 is in ohmic contact with the n⁺⁺-type source regions 7 and the p⁺⁺-type contact regions 8 via contact holes opened in the interlayer insulating film 11. The source electrode 12 is electrically insulated from the gate electrodes 10 by the interlayer insulating film 11. A source electrode pad 26 is disposed on the source electrode 12.

In the active region 40 depicted in FIGS. 2 and 3, while three trench MOS structures are illustrated, more trench MOS (insulated gate made of metal-oxide film-semiconductor) structures may be arranged in parallel.

In the intermediate region 41, a gate ring 24 for connecting the gate electrodes 10 with the gate electrode pad 27 is formed in a substantially rectangular shape surrounding the periphery of the active region 40 in a plan view of the device. In the intermediate region 41, an initial oxide film 17 functioning as a field oxide film for insulating the p⁺⁺-type contact regions 8 is disposed on the p⁺⁺-type contact regions 8. A film constituting the gate insulating films 9 is disposed on the initial oxide film 17, and a polysilicon 18 connected to the gate electrodes 10 is disposed on the film constituting the gate insulating films 9. The gate ring 24 is connected to the polysilicon 18 through an opening disposed in the interlayer insulating film 11.

In the intermediate region 41, a source ring 25 for extracting electric charge is formed in a substantially rectangular shape surrounding a periphery of the gate ring 24. The source ring 25 is connected to the source electrode pad 26 at a source ring connection portion 28.

The source ring connection portion 28 may be one of multiple source ring connection portions. The source ring 25 is connected to the p⁺⁺-type contact regions 8 through an opening disposed in the interlayer insulating film 11, the film constituting the gate insulating films 9 and the initial oxide film 17. This allows the source ring 25 to lead the current generated in the intermediate region 41 to the source electrode 12.

The terminal structure region 42 is free of the p-type base layer 6 and the n⁻-type high concentration region and in the terminal structure region 42, the n⁻-type drift layer 2 is exposed, and a voltage withstanding structure such as a guard ring structure 21 or a junction termination extension (JTE) structure is disposed on the n⁻-type drift layer 2.

In the guard ring structure 21, p⁻-type regions arranged in descending order of impurity concentration in a direction from an inner side (the intermediate region 41 side) to an outer side (end of the n⁺-type silicon carbide substrate 1) have a substantially rectangular shape surrounding the periphery of the active region 40 and the intermediate region 41, in a plan view. Instead of changing the impurity concentration, spacing between the p-type regions may be increased in a direction from the inner side to the outer side, or the width of the p-type regions may be decreased. In a case of the JTE structure, multiple connected p-type regions arranged in descending order of impurity concentration in a direction from the inner side (the intermediate region 41 side) to the outer side (end of the n⁺-type silicon carbide substrate 1) have a substantially rectangular shape surrounding the periphery of the active region 40 and the intermediate region 41, in a plan view of the device. An n⁺⁺-type region 23 serving as a channel stopper is arranged outside these voltage withstanding structures. The interlayer insulating film 11, the gate insulating film 9, and the initial oxide film 17 are disposed on the surfaces of the voltage withstanding structures and the n⁺⁺-type region 23, and a protective film (not depicted) containing a polyimide or the like is disposed on a top surface of the trench MOSFET 50.

A boundary between the active region 40 and the intermediate region 41 is a bottom of the step between the interlayer insulating film 11 and the film constituting the gate insulating films 9 disposed on the p⁺⁺-type contact regions 8 and the boundary between the intermediate region 41 and the terminal structure region 42 is the bottom of the step of the initial oxide film 17.

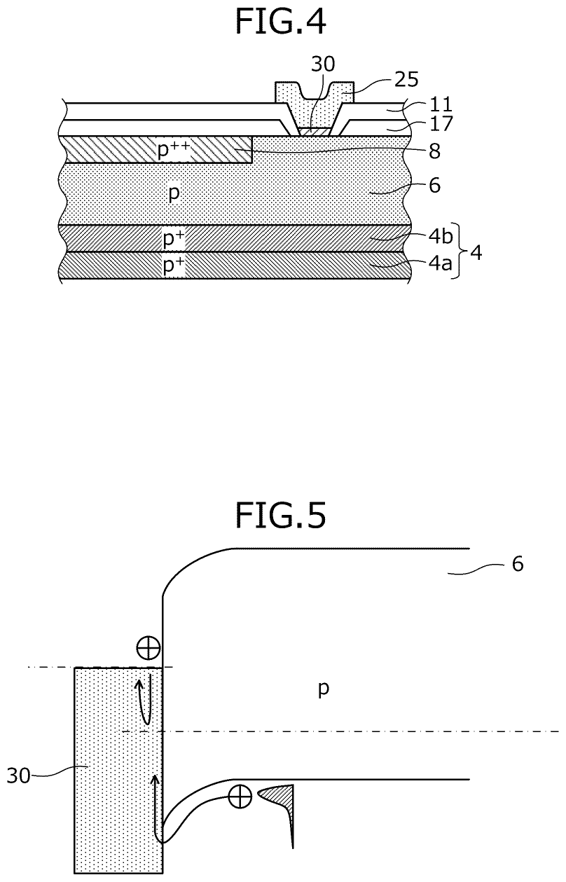

FIG. 4 is a cross-sectional view depicting a first structure of the source ring of the silicon carbide semiconductor device according to the first embodiment. The configuration of the p-type region may differ depending on the design. In the first embodiment, the p-type region is composed of the first p⁺-type region 4a, the second p⁺-type region 4b, the p-type base layer 6, and the p⁺⁺-type contact regions 8. The p-type region has this structure in second to fourth embodiments described below. The structures below the n⁻-type drift layer 2 are omitted. The left side of FIG. 4 is the active region 40 side and the right side is the terminal structure region 42 side. As depicted in FIG. 4, in the first structure of the source ring according to the first embodiment, the source ring 25 is in Schottky contact with the p-type base layer 6 through a Schottky electrode 30. This allows the holes to be extracted from the p-type base layer 6 and also prevents holes from being injected from the p-type base layer 6 into the n⁻-type drift layer 2.

FIG. 5 is a band diagram, during forward bias (positive voltage at drain), in the first structure of the source ring of the silicon carbide semiconductor device according to the first embodiment. FIG. 5 depicts a band gap of the p-type base layer 6. The Fermi distribution function×the hole state density in the valence band of the p-type base layer 6 is depicted. Under forward bias (positive voltage at drain), the Fermi level of the Schottky electrode 30 is higher than the Fermi level of the p-type base layer 6, the band bending is small, and the potential barrier against holes is small, whereby the holes may be drawn from the p-type base layer 6 to the Schottky electrode 30.

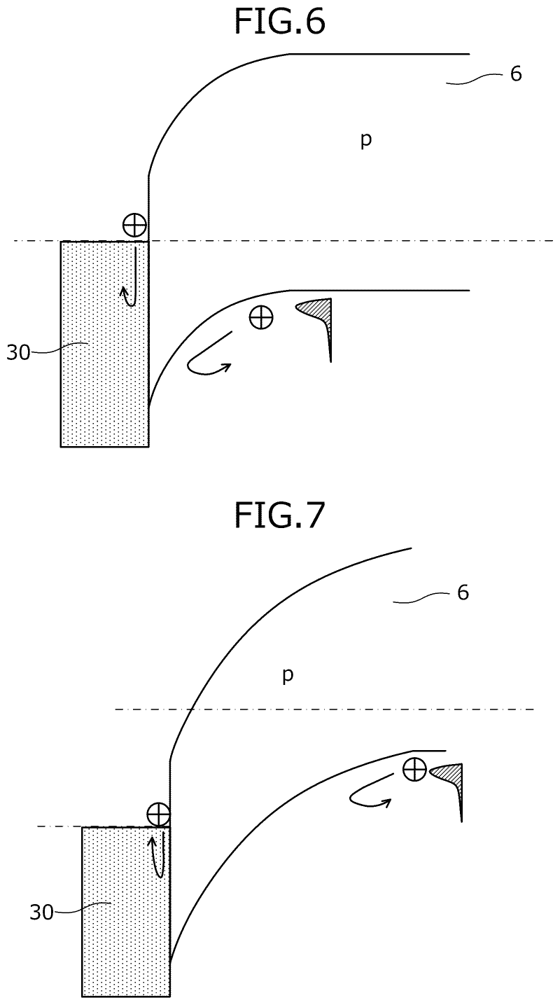

FIG. 6 is a band diagram, at thermal equilibrium (drain is 0V), in the first structure of the source ring of the silicon carbide semiconductor device according to the first embodiment. At thermal equilibrium (0V at drain), the Fermi level of the Schottky electrode 30 becomes the same as the Fermi level of the p-type base layer 6.

FIG. 7 is a band diagram during reverse bias (negative voltage at drain) of the first structure of the source ring of the silicon carbide semiconductor device according to the first embodiment. During reverse bias (negative voltage at drain), the Fermi level of the Schottky electrode 30 becomes lower than the Fermi level of the p-type base layer 6, but the energy difference between the energy level of the Schottky electrode that is not filled with electrons (may be considered to have holes) and the valence band of the p-type base layer 6 is large, whereby holes are not injected from the Schottky electrode 30.

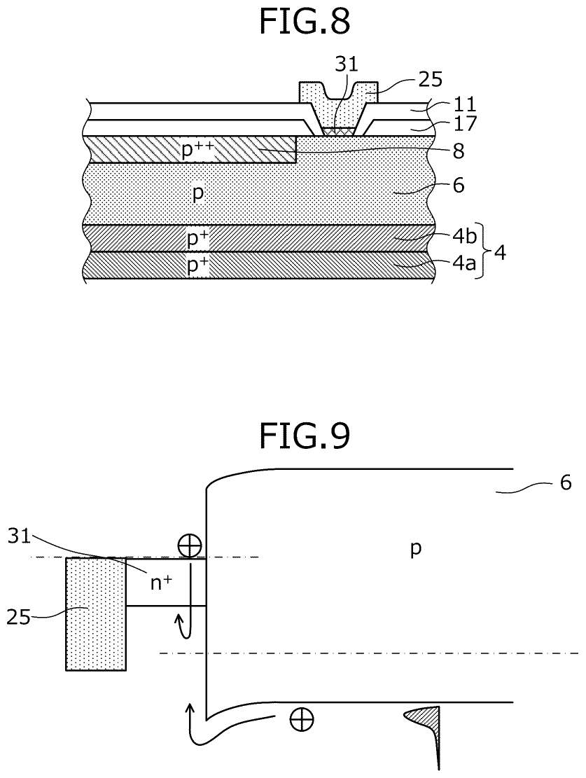

FIG. 8 is a cross-sectional view depicting a second structure of the source ring of the silicon carbide semiconductor device according to the first embodiment. The configuration of the p-type region may differ depending on the design. The same configuration as that in FIG. 4 is depicted here. The left side of FIG. 8 is the active region 40 side and the right side is the terminal structure region 42 side. In the second structure of the source ring of the first embodiment, the source ring 25 is in heterojunction with the p-type base layer 6 through a silicon layer 31 containing, for example, a polysilicon. In this way, by forming the heterojunction of a semiconductor (for example, Si) having the large band offset on the valence band side relative to the SiC in the p-type region, holes may be drawn from the p-type base layer 6 and the injection of the holes from the p-type base layer 6 may be prevented.

FIG. 9 is a band diagram during forward bias (positive voltage at drain) in the second structure (n⁺-type) of the source ring of the silicon carbide semiconductor device according to the first embodiment. As depicted in FIG. 9, during forward bias (positive voltage at drain), the Fermi level of the silicon layer 31 is higher than the Fermi level of the p-type base layer 6, the band bending is smaller, and the potential barrier against holes is smaller, whereby holes may be drawn from the p-type base layer 6 to the silicon layer 31. The silicon layer 31 is n⁺-type, but may be a polysilicon free of dopants.

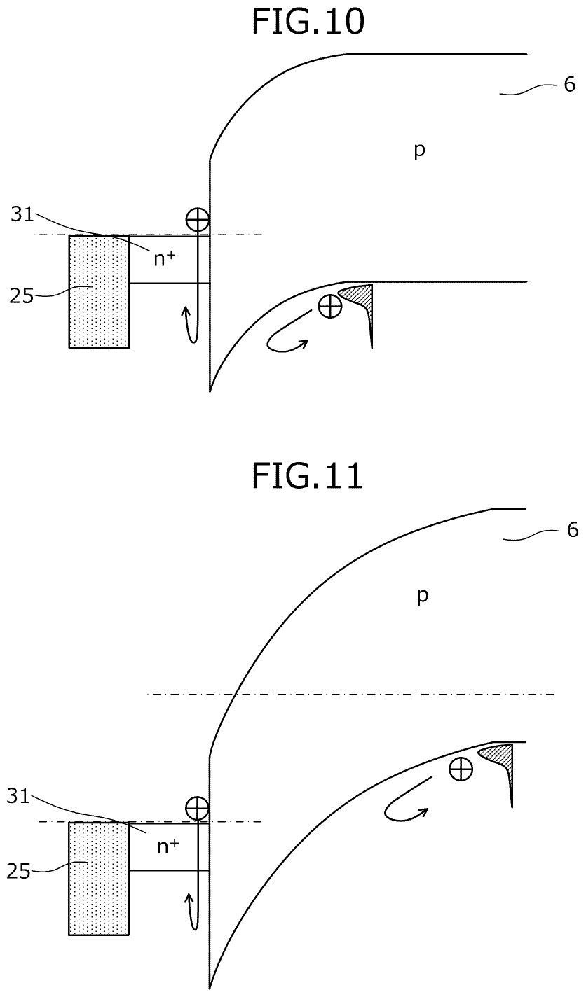

FIG. 10 is a band diagram, at thermal equilibrium (0V at drain) in the second structure (n⁺-type) of the source ring of the silicon carbide semiconductor device according to the first embodiment. As depicted in FIG. 10, at thermal equilibrium (0V at drain), the Fermi level of the silicon layer 31 is the same as the Fermi level of the p-type base layer 6.

FIG. 11 is a band diagram, during reverse bias (negative voltage at drain), in the second structure (n⁺-type) of the source ring of the silicon carbide semiconductor device according to the first embodiment. As depicted in FIG. 11, during reverse bias (negative voltage at drain), the Fermi level of the silicon layer 31 is lower than the Fermi level of the p-type base layer 6, but the energy difference between the energy level of the n⁺ silicon conduction band that is not filled with electrons (may be considered to have holes) and the valence band of the p-type base layer 6 is large, and the holes are not injected from the silicon layer 31 to the p-type base layer 6.

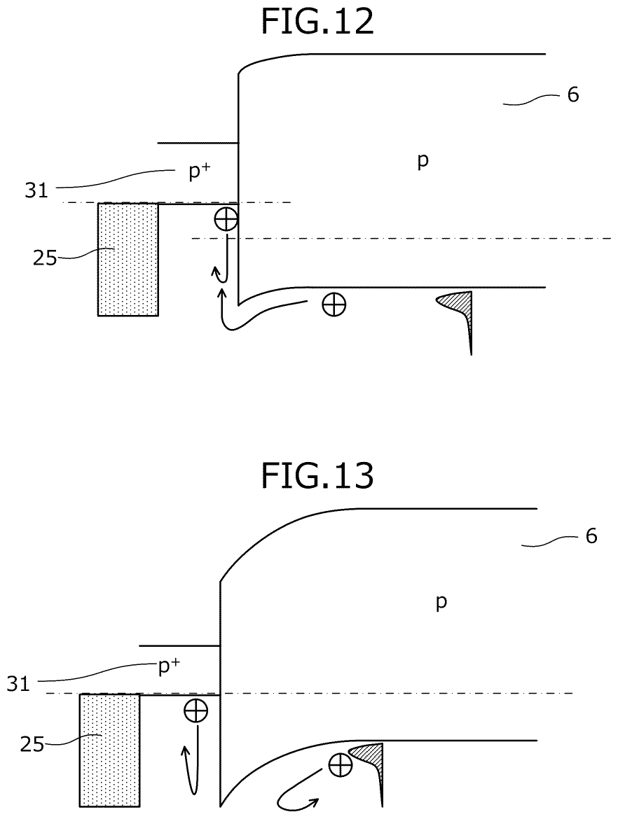

FIG. 12 is a band diagram, during forward bias (positive voltage at drain), in the second structure (p⁺-type) of the source ring of the silicon carbide semiconductor device according to the first embodiment. As depicted in FIG. 12, during forward bias (positive voltage at drain), the Fermi level of the silicon layer 31 is higher than the Fermi level of the p-type base layer 6, the band bending is small, and the potential barrier against holes is small, whereby holes may be drawn from the p-type base layer 6 to the silicon layer 31. The silicon layer 31 may be a p⁺-type polysilicon free of dopants.

FIG. 13 is a band diagram, at thermal equilibrium (0V at drain), in the second structure (p⁺-type) of the source ring of the silicon carbide semiconductor device according to the first embodiment. As depicted in FIG. 13, during thermal equilibrium (0V at drain), the Fermi level of the silicon layer 31 is the same as the Fermi level of the p-type base layer 6.

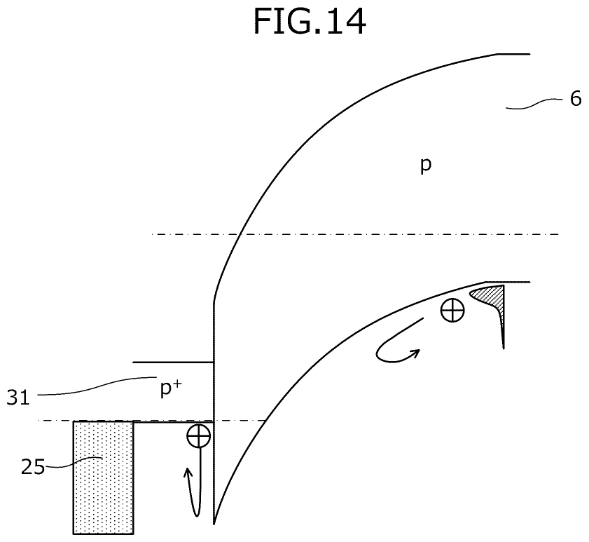

FIG. 14 is a band diagram, during reverse bias (negative voltage at drain), in the second structure (p⁺-type) of the source ring of the silicon carbide semiconductor device according to the first embodiment. As depicted in FIG. 14, during reverse bias (negative voltage at drain), the Fermi level of the silicon layer 31 is lower than the Fermi level of the p-type base layer 6, but the energy difference between the energy level at the top of the p⁺ silicon valence band where the holes are present and the valence band of the p-type base layer 6 is large, whereby the holes are prevented from being injected from the p⁺ silicon layer 31 to the p-type base layer 6. Due to the energy difference in the case of the n⁺-type being larger than the energy difference in the case of the p⁺-type, the first structure (n⁺-type) is more preferable than the second structure (p⁺-type).

Thus, by making the contact between the source ring 25 and the p-type base layer 6 a Schottky junction or heterojunction, the holes may be sufficiently drawn from the p-type base layer 6 in the source ring 25 when dV/dt is applied, and the holes may also be prevented from being injected from the source ring 25 when the parasitic diode of the MOSFET 50 is forward biased. Accordingly, the concentration of current in the source ring 25 may be suppressed to thereby hinder the growth of stacking faults while ensuring dV/dt resistance.

A method of manufacturing a silicon carbide semiconductor device according to the first embodiment may include fabrication by the following methods. Here, an example of fabricating a MOSFET with a breakdown voltage class of 1200V is described. First, an n⁺-type silicon carbide substrate (semiconductor wafer) 1 containing single crystal silicon carbide is prepared, the n⁺-type silicon carbide substrate 1 being doped with an n-type impurity (dopant) such as nitrogen (N) to have an impurity concentration of, for example, 2.0×10¹⁹/cm³. A front surface of the n⁺-type silicon carbide substrate 1 may be, for example, a (0001) plane having an off angle of about 4 degrees in the <11-20>direction. The n⁻-type drift layer 2 doped with the n-type impurity such as nitrogen to have an impurity concentration of, for example, 1.0×10¹⁶/cm³ is grown by epitaxy on the front surface of the n⁺-type silicon carbide substrate 1 and has a thickness of, for example, 10 μm.

The n-type high concentration region may be selectively formed in the surface layer of the n⁻-type drift layer 2 by photolithography and ion implantation. In this ion implantation, for example, an n-type impurity (dopant) such as nitrogen may be implanted to achieve a concentration of 1×10¹⁷/cm³.

The first p⁺-type base regions 3 and a first p⁺-type region 4a are selectively formed in the n⁻-type drift layer 2 by photolithography and ion implantation. Next, the second p⁺-type region 4b is selectively formed in the surface layer of the n-type drift layer 2. In this ion implantation, for example, a p-type impurity (dopant) such as aluminum (Al) may be implanted in the first p⁺-type base regions 3, the first p⁺-type region 4a, and the second p⁺-type region 4b so that impurity concentrations thereof become 5.0×10¹⁸/cm³.

The p⁻-type base layer 6 doped with a p-type impurity such as aluminum to have an impurity concentration of, for example, 2.0×10¹⁷/cm³ is grown by epitaxy on the surface of n⁻-type drift layer 2 and has a thickness of, for example, 1.3 μm.

In the processes up to here, the silicon carbide semiconductor substrate is fabricated in which the n⁻-type drift layer 2 and the p-type base layer 6 are stacked in this order on the front surface of the n⁺-type silicon carbide substrate 1. The n⁺⁺-type source regions 7 and the p⁺⁺-type contact regions 8 in the surface layer of the p-type base layer 6 are formed by repeating, under different ion implantation conditions, a set of processes including forming an ion implantation mask by photolithography and etching, ion implantation using the ion implantation mask, and removing the ion implantation mask.

In the terminal structure region 42, the guard ring structure 21 is selectively formed by photolithography and ion implantation. In the terminal structure region 42, the n⁺⁺-type region 23 is selectively formed by photolithography and ion implantation.

A heat treatment (annealing) is performed thereby activating, for example, the p⁺-type base regions 3, the n⁺⁺-type source regions 7, the p⁺⁺-type contact regions 8, the guard ring structure 21, and the n⁺⁺-type region 23. The temperature of the heat treatment may be, for example, about 1700 degrees C. The duration of the heat treatment may be, for example, about 2 minutes. As described above, the ion implanted regions may be activated collectively by a single heat treatment, or may be activated by performing the heat treatment each time ion implantation is performed.

An oxide film is formed on the surface of the p-type base layer 6 (i.e., the surfaces of the n⁺⁺-type source regions 7 and the p⁺⁺-type contact regions 8). The oxide film may be, for example, a thermally oxidized film or a deposited film. The thickness of a portion of the oxide film in the active region 40 is thinner than a thicker portion of the oxide film formed in the outer periphery of the terminal structure region 42.

A resist mask (not depicted) having a predetermined opening is formed on the surface of the oxide film by photolithography. Using the resist mask as a mask, an opening is formed in the oxide film by dry etching. The resist mask is removed and the oxide film is used as a mask to form the trenches 16 by anisotropic dry etching, the trenches 16 penetrating the n⁺⁺-type source regions 7 and the p-type base layer 6 and reaching the n⁻-type drift layer 2. The bottoms of the trenches 16 are in the first p⁺-type base regions 3.

Isotropic etching and sacrificial oxidation are performed with the oxide film in place. This process removes damage of the trenches 16 and rounds the bottoms of the trenches 16. The isotropic etching and the sacrificial oxidation may be performed in any order. The isotropic etching or the sacrificial oxidation may be performed alone. The thinner portion of the oxide film used as a mask for forming the trenches 16 is then removed. At this time, the thinner portion of the oxide film and the sacrificial oxide film may be removed at the same time. Since the oxide film has a thinner portion, and a thicker portion is in the terminal structure region 42, overall etching is performed to remove the thinner portion of the oxide film, leaving the thicker portion of the oxide film in the terminal structure region 42. The sacrificial oxide film (not depicted) may be removed with the thinner portion of the oxide film. The oxide film may be removed by photolithography and etching so as to be left in the terminal structure region 42. The oxide film (thicker portion of the oxide film) left in the terminal structure region 42 constitutes the initial oxide film 17.

A film constituting the gate insulating films 9 is formed along the surfaces of the initial oxide film 17, the n⁺⁺-type source regions 7 and the p⁺⁺-type contact regions 8, and the bottoms and sidewalls of the trenches 16. The film constituting the gate insulating films 9 may be formed by thermal oxidation at a temperature of about 1000 degrees C. in an oxygen atmosphere. The film constituting the gate insulating films 9 may also be formed by a method of deposition by chemical reaction such as that for a high temperature oxide (HTO).

For example, a polycrystalline silicon layer doped with phosphorus atoms (P) is formed on the film constituting the gate insulating films 9. The polycrystalline silicon layer is formed so as to be embedded in the trenches 16. The polycrystalline silicon layer is patterned so as to be left in the trenches 16, thereby forming the gate electrodes 10. A portion of each of the gate electrodes 10 may protrude toward the source electrode 12 above the trench 16 thereof.

The interlayer insulating film 11 is formed by, for example, depositing a phosphate glass (PSG) so as to cover the film constituting the gate insulating films 9 and the gate electrodes 10 and have a thickness of about 1 μm. The interlayer insulating film 11 and the film constituting the gate insulating films 9 are patterned and selectively removed to form contact holes, whereby the n⁺⁺-type source regions 7 and the p⁺⁺-type contact regions 8 are exposed and the gate insulating films 9 formed. Thereafter, a heat treatment (reflow) is performed to flatten the interlayer insulating film 11.

A conductive film constituting the source electrode 12 is formed in the contact holes and on the interlayer insulating film 11. The conductive film is selectively removed so as to be left as the source electrode 12 only in the contact holes, for example. In the intermediate region 41, a conductive film constituting the Schottky electrode 30 or the silicon layer 31 is formed in the contact holes and on the interlayer insulating film 11. This conductive film is selectively removed so as to leave a portion constituting the Schottky electrode 30 or the silicon layer 31 only in the contact hole, for example. The source electrode 12 is formed to be in ohmic contact with the p⁺⁺-type contact regions 8 and the p-type base layer 6, the Schottky electrode 30 is formed to be in Schottky junction with the p-type base layer 6, and the silicon layer 31 is formed to be in heterojunction with the p-type base layer 6.

For example, by sputtering, an aluminum film is disposed so as to cover the source electrode 12 and the interlayer insulating film 11 and have a thickness of, for example, about 5 μm. Thereafter, the aluminum film is selectively removed and left to cover the active region 40 and the intermediate region 41 of the entire device, thereby forming the gate ring 24, the source ring 25, the source electrode pad 26, and the gate electrode pad 27. Thereafter, a polyimide is applied as a surface passivation film, for example, by spin coating, and is patterned by photolithography, and heat-treated (cured) to thereby form a protective film (not depicted).

The back electrode 13 constituted by, for example, a nickel (Ni) film is formed on the back surface of the silicon carbide semiconductor substrate (back surface of the n⁺-type silicon carbide substrate 1). Then, a heat treatment is performed at a temperature of, for example, about 970 degrees C., thereby forming an ohmic contact between the n⁺-type silicon carbide substrate 1 and the back electrode 13.

The back electrode 13 may be, for example, a stacked film in which titanium (Ti), nickel (Ni) and gold (Au) are stacked in order the stated, or may be a stacked film of nickel (Ni), titanium (Ti), molybdenum (Mo) and gold (Au). As described, the semiconductor device depicted in FIGS. 1 to 3 is completed.

As described, according to the first embodiment, the contact between the source ring and the p-type base layer is a Schottky junction or a heterojunction, whereby at the source ring, the holes may be sufficiently drawn from the p-type base layer when dV/dt is applied, and the holes may be prevented from being injected from the source ring when a parasitic diode of the MOSFET is forward-biased. Accordingly, the concentration of current in the source ring may be suppressed to thereby hinder the growth of stacking faults while ensuring dV/dt capability.

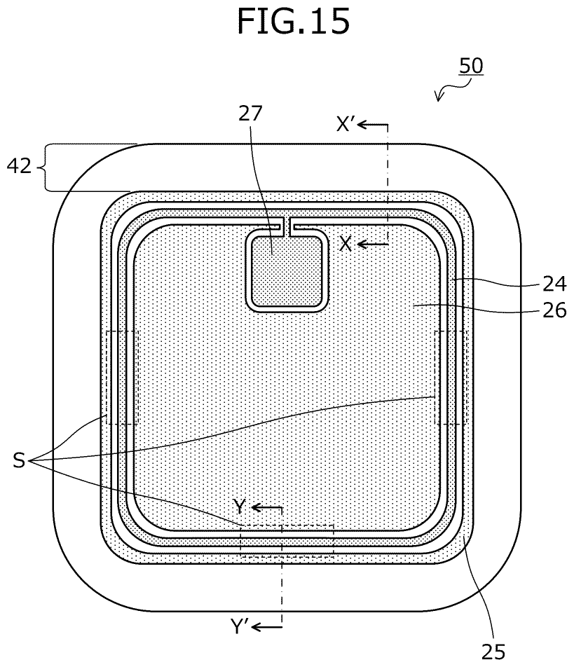

A second embodiment is described. FIG. 15 is a top view depicting a structure of the silicon carbide semiconductor device according to the second embodiment. As depicted in FIG. 15, the second embodiment has a diode or a resistor disposed between the source ring 25 and the source electrode 12.

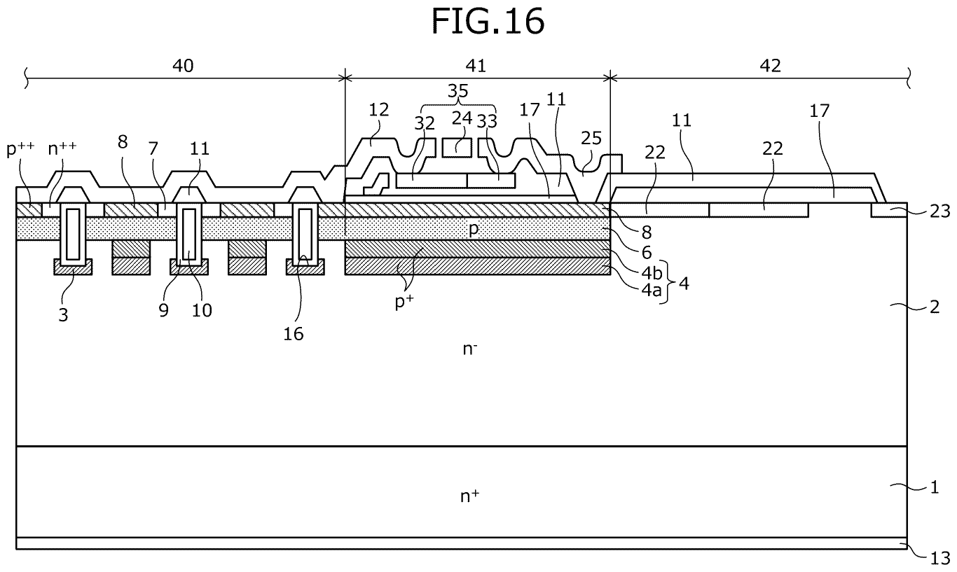

FIG. 16 is a cross-sectional view depicting a first structure of the source ring in the silicon carbide semiconductor device according to the second embodiment, along cutting line Y-Y′ in FIG. 15. In terminal structure region 42 in FIG. 16, a JTE structure 22 is used, however, a guard ring structure may also be used. FIG. 17 is a top view of regions S of the first structure of the source ring in the silicon carbide semiconductor device according to the second embodiment. In FIG. 17, a region where the source ring 25 contacts p⁺⁺-type contact regions 8 is depicted by a source ring contact 29. As depicted in FIGS. 16 and 17, in the first structure of the source ring of the first embodiment, a diode 35 is disposed between the source ring 25 and the source electrode 12, whereby an electric current may flow from the source ring 25 to the source electrode 12 and an electronic current flowing in the opposite direction may be blocked. For example, the diode 35 is constituted by the n⁺-type polysilicon layer 32 on the source electrode 12 side and a p⁺-type polysilicon layer 33 on the source ring 25 side. The diode 35 is disposed on the p⁺⁺-type contact regions 8 on a silicon carbide semiconductor substrate through the initial oxide film 17 and the gate insulating film 7.

This allows the holes to be drawn from the p-type base layer 6 in the source ring 25 when dV/dt is applied, and prevents the holes from being injected from the source ring 25 when the parasitic diode of the MOSFET 50 is forward biased. Thus, the concentration of current in the source ring 25 may be suppressed to thereby hinder the growth of stacking faults while ensuring a dV/dt capability.

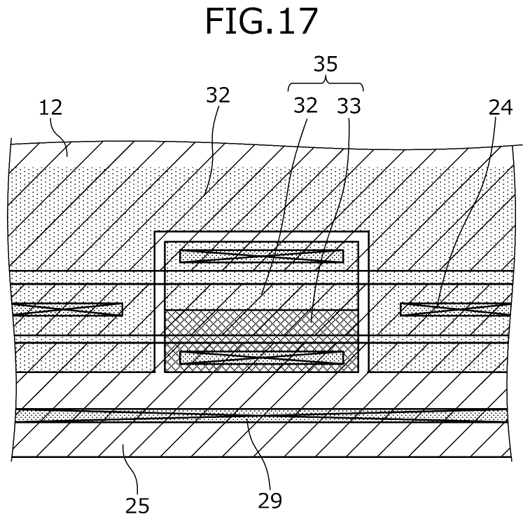

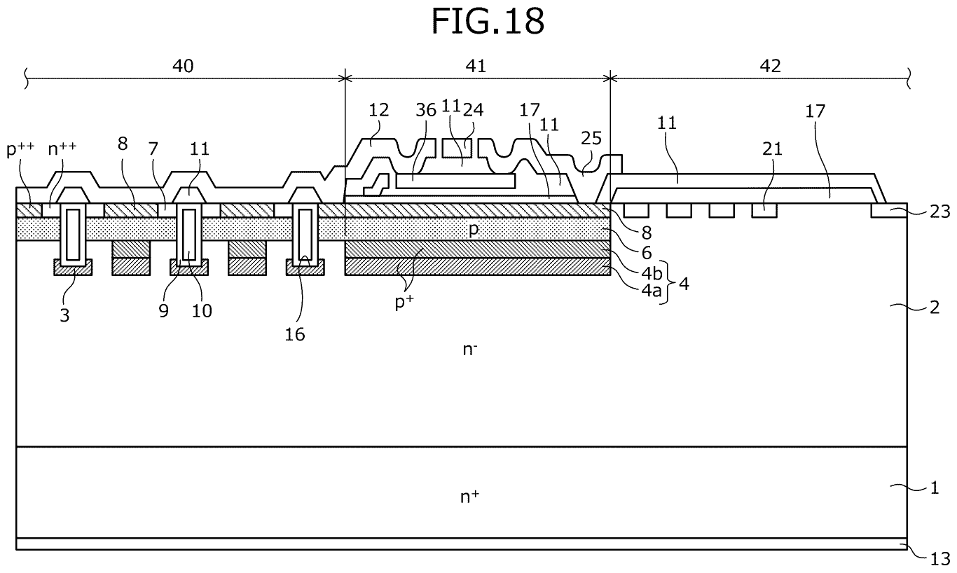

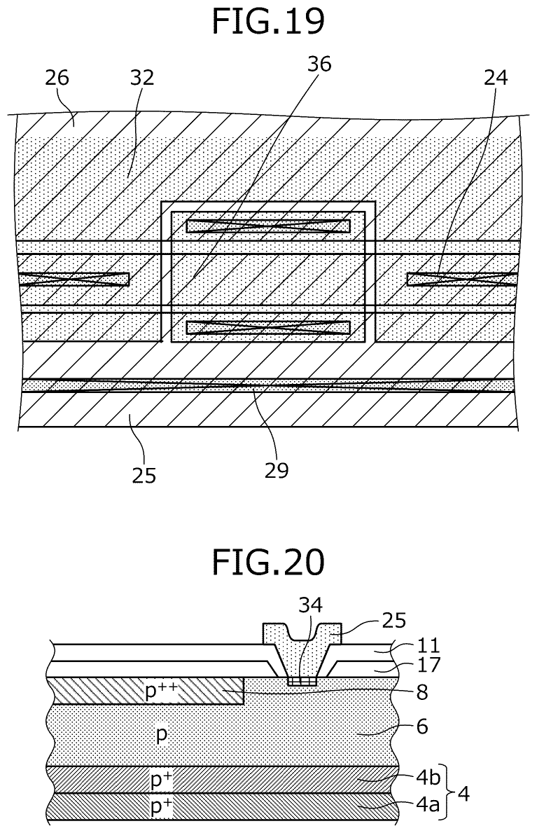

FIG. 18 is a cross-sectional view depicting a second structure of the source ring of the silicon carbide semiconductor device according to the second embodiment, along cutting line Y-Y′ in FIG. 15. FIG. 19 is a top view depicting the regions S of the second structure of the source ring of the silicon carbide semiconductor device according to the second embodiment. In FIG. 19, a region where the source ring 25 contacts the p⁺⁺-type contact regions 8 is depicted by the source ring contact 29. As depicted in FIGS. 18 and 19, in the second structure of the source ring of the second embodiment, a resistor 36 constituted by an n⁺-type polysilicon layer is disposed between the source ring 25 and the source electrode 12. The resistor 36 may mitigate the injection of holes from the source ring 25 when a parasitic diode of the MOSFET 50 is forward biased. The resistor 36 may be preferably an n⁺-type polysilicon layer having a high impurity concentration of, for example, 1×10¹⁹/cm³ or more.

As described, according to the second embodiment, when dV/dt is applied, holes may be drawn from the p-type base layer at the source ring, and when a parasitic diode of the MOSFET is forward biased, the mitigate the injection of holes from the source ring may be reduced. In the second structure, the n⁺-type polysilicon layer reduces the dV/dt capability, but the reduction poses no practical problem. Thus, the concentration of current in the source ring may be suppressed to thereby hinder the growth of stacking faults while ensuring the dV/dt capability.

A third embodiment is described. In the third embodiment, the contact resistance between the source ring 25 and the p-type region is made larger than the contact resistance between the source electrode 12 of the active region 40 and the p-type region. A top view according to the third embodiment is the same as that for the first embodiment and therefore, is not described.

FIG. 20 is a cross-sectional view depicting a first structure of the source ring of the silicon carbide semiconductor device according to the third embodiment. The left side of FIG. 20 is the active region 40 side and the right side is the terminal structure region 42 side. As depicted in FIG. 20, in the first structure of the source ring 25 of the third embodiment, the source ring 25 is in ohmic contact with the p-type base layer 6 through a silicide layer 34. Thus, the source electrode 12 in the active region 40 is in contact with the p⁺⁺-type contact regions 8, and a location that the source ring 25 contacts is free of the p⁺⁺-type contact regions 8, whereby the source ring 25 is in contact with the p-type base layer 6, thereby increasing the contact resistance.

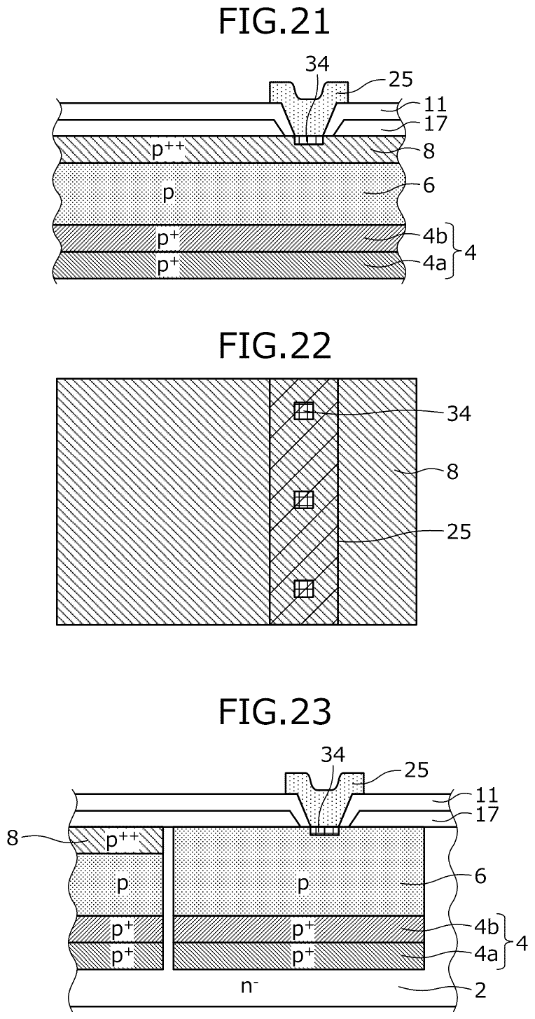

FIG. 21 is a cross-sectional view depicting a second structure of the source ring of the silicon carbide semiconductor device according to the third embodiment. The left side of FIG. 21 is the active region 40 side and the right side is the terminal structure region 42 side. As depicted in FIG. 21, in the second structure of the source ring 25 of the third embodiment, the source ring 25 is in ohmic contact with the p⁺⁺-type contact regions 8 in the silicide layer 34. FIG. 22 is the top view depicting the second structure of the source ring of the silicon carbide semiconductor device according to the third embodiment. The left side of FIG. 22 is the active region 40 side and the right side of is the terminal structure region 42 side. To make the contact resistance of the source ring 25 larger than the contact resistance of the active region 40, an average area of the region where the source ring 25 and the p⁺⁺-type contact regions 8 are in ohmic contact is made smaller than the average area of the region where the source electrode 12 and the p⁺⁺-type contact regions 8 are in ohmic contact in the active region 40. For example, as depicted in FIG. 22, only a portion of the silicide layer 34 of the source ring 25 is in ohmic contact with the p⁺⁺-type contact regions 8. Thus, the contact resistance is made larger by making the average area of the region that the silicide layer 34 of the source ring 25 contacts smaller.

In the second structure of the source ring 25 of the third embodiment, the source ring 25 and the p-type base layer 6 may be in ohmic contact as in the first structure of the source ring 25 of the third embodiment.

As described, according to the third embodiment, when dV/dt is applied, the holes may be drawn from the p-type base layer at the source ring, and the mitigate the injection of holes from the source ring may be reduced when a parasitic diode of the MOSFET is forward biased. While the dV/dt capability is reduced by the large contact resistance, the reduction raises no practical problem. Thus, the concentration of current in the source ring may be suppressed to thereby hinder the growth of stacking faults while ensuring the dV/dt capability.

A fourth embodiment is described. In the fourth embodiment, the p-type region of the active region 40 and the p-type region connected to the source ring 25 are apart from each other. The fourth embodiment is used in combination with the first to third embodiments. In the fourth embodiment, effects of the first to third embodiments are enhanced by separating the p-type region, whereby most of the current in a vicinity of the active region 40 flows into the source ring 25 when dV/dt is applied.

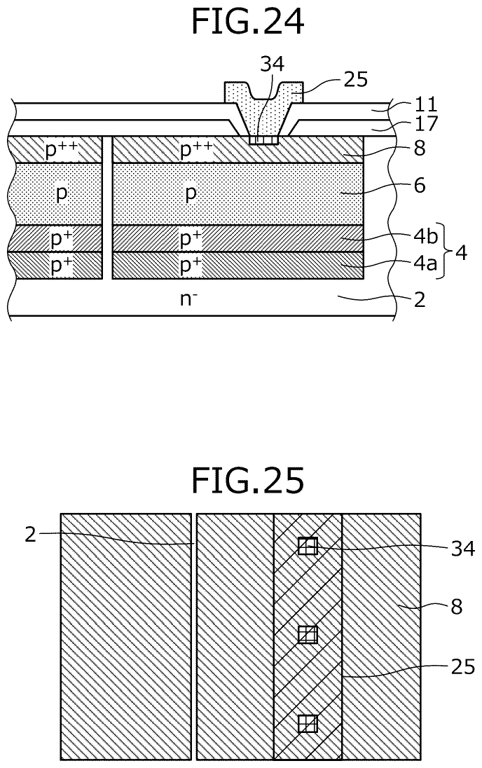

FIG. 23 is a cross-sectional view depicting a first structure of the source ring of the silicon carbide semiconductor device according to the fourth embodiment. The left side of FIG. 23 is the active region 40 side and the right side is the terminal structure region 42 side. FIG. 23 depicts an instance in which the fourth embodiment is applied to the first structure of the source ring of the third embodiment. FIG. 24 is a cross-sectional view depicting a second structure of the source ring of the silicon carbide semiconductor device according to the fourth embodiment. FIG. 25 is a top view depicting the second structure of the source ring of the silicon carbide semiconductor device according to the fourth embodiment. FIGS. 24 and 25 depict an instance in which the fourth embodiment is applied to the second structure of the source ring of the third embodiment. The respective left sides of FIGS. 24 and 25 are the active region 40 side and the respective right sides are the terminal structure region 42 side.

As described, according to the fourth embodiment, effects of the first to third embodiments are enhanced by separating the p-type region in the active region and the p-type region connected to the source ring, whereby most of the current in a vicinity of the active region 40 flows into the source ring 25 when dV/dt is applied.

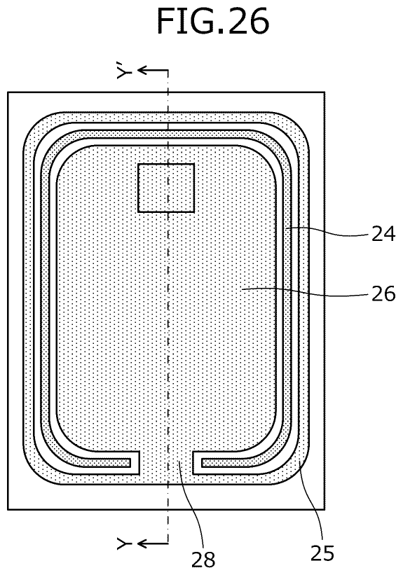

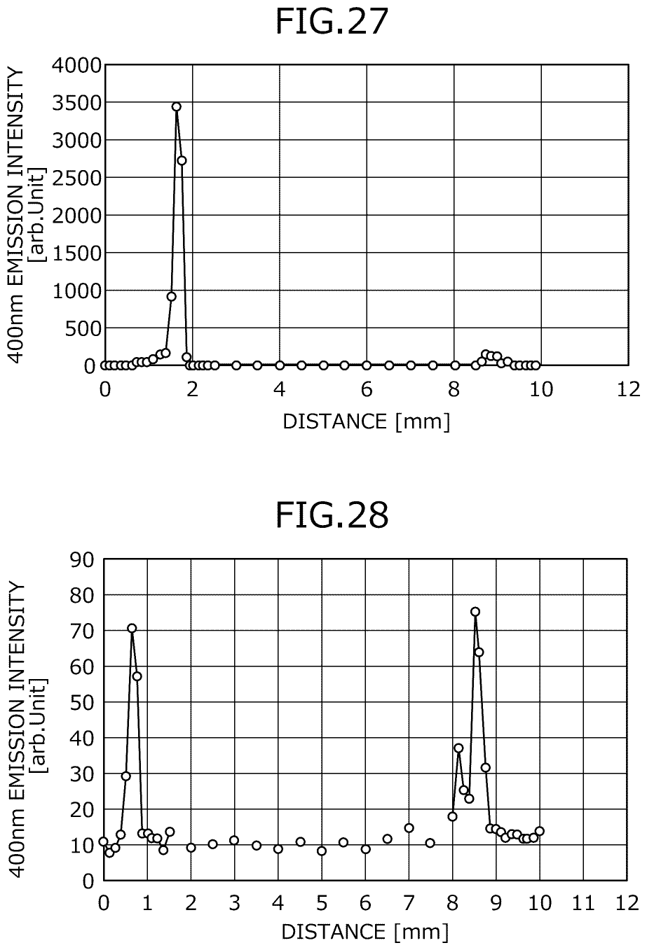

The silicon carbide semiconductor device was fabricated having the first structure of the source ring of the third embodiment and light emission of the parasitic diode when energized was compared with the light emission of an existing silicon carbide semiconductor device when energized. FIG. 26 is a top view depicting a structure of the silicon carbide semiconductor device of an example. FIG. 27 is a graph depicting the light emission intensity distribution from the surface along cutting line Y-Y′ during reverse conduction (parasitic diode energization) of the existing silicon carbide semiconductor device. FIG. 28 is a graph depicting the light emission intensity distribution from the surface along cutting line Y-Y′ during reverse conduction (parasitic diode energization) in the first structure of the source ring of the silicon carbide semiconductor device according to the third embodiment. In FIGS. 27 and 28, a vertical axis depicts the emission intensity of light with a wavelength of 400 nm and a horizontal axis depicts the distance from a Y-side end of the silicon carbide semiconductor device, in units of nm.

As depicted in FIG. 27, in the existing silicon carbide semiconductor device, strong emission is detected near the source ring connection (between 0 mm and 2 mm), and in direction away from the source ring connection, the emission intensity decreases due to voltage drop caused by lateral resistance. On the other hand, as depicted in FIG. 28, in the third embodiment it was confirmed that peak intensity near the source ring connection (between 0 mm and 2 mm) is reduced to about 1/500 of the existing level.

The reduction in emission near the source ring connection is a result of the reduction in the injection of the holes from the source ring 25 when the parasitic diode is forward biased, indicating that, in the present disclosure, the concentration of current in the source ring 25 may be suppressed to thereby hinder the growth of stacking faults. In both the existing silicon carbide semiconductor device and the silicon carbide semiconductor device in the third embodiment, the dV/dt capability at low temperatures meets the specified value and the dV/dt capability is ensured.

In the foregoing, while a case where a MOS gate structure is configured on the first main surface of a silicon carbide substrate is described as an example in the present disclosure, without limited hereto, various modifications are possible, for example, the surface orientation of the main surface of the substrate may be changed. In the embodiments of the present disclosure, while a trench-type MOSFET is described as an example, without limitation hereto, application is possible to semiconductor devices of various configurations including MOS-type semiconductor devices such as trench-type IGBTs. In the present disclosure, while a first conductivity type is assumed to be an n-type and a second conductivity type is assumed to be a p-type in the embodiments, the present disclosure is similarly implemented when the first conductivity type is a p-type and the second conductivity type is an n-type.

According to the disclosure above, by forming the contact between the source ring and the p-type base layer (the second semiconductor region of the second conductivity type) as a Schottky junction, holes may be sufficiently extracted from the p-type base layer at the source ring when dV/dt is applied and injection of holes from the source ring is prevented when the MOSFET parasitic diode is forward biased. Thus, the concentration of current in the source ring may be suppressed to thereby hinder the growth of stacking faults while ensuring dV/dt capability.

The semiconductor device according to the present disclosure achieves an effect in that current concentration in the source ring portion may be suppressed to thereby hinder the growth of stacking faults.

As described above, the semiconductor device according to the present disclosure is useful for high-voltage semiconductor devices used in power converting equipment and power supply devices for various industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate of a first conductivity type, the semiconductor substrate having
an active region through which a main current flows,
a terminal region surrounding a periphery of the active region in a top view of the semiconductor substrate, and
an intermediate region between the active region and the terminal region,
the semiconductor substrate having a first main surface and a second main surface opposite to each other;
a front electrode provided in the active region, on the first main surface of the semiconductor substrate;
a first semiconductor region of a second conductivity type formed in the semiconductor substrate, and being connected to the front electrode;
a second semiconductor region of the second conductivity type formed in the semiconductor substrate, for extracting hole current; and
a source ring provided in the intermediate region, the source ring being electrically connected to the front electrode and connected to the second semiconductor region, wherein
a contact between the front electrode in the active region and the first semiconductor region is an ohmic contact, and
a contact between the source ring in the intermediate region and the second semiconductor region includes a Schottky junction or a heterojunction.

2. The semiconductor device according to claim 1, wherein the heterojunction is formed by using a semiconductor layer having a larger band offset on a valence band side than the second semiconductor region.

3. The semiconductor device according to claim 2, wherein the semiconductor layer contains silicon.

4. A semiconductor device comprising:
a semiconductor substrate of a first conductivity type, the semiconductor substrate having
an active region through which a main current flows,
a terminal region surrounding a periphery of the active region in a top view of the semiconductor substrate, and
an intermediate region between the active region and the terminal region,
the semiconductor substrate having a first main surface and a second main surface opposite to each other;
a front electrode provided in the active region, on the first main surface of the semiconductor substrate;
a first semiconductor region of a second conductivity type formed in the semiconductor substrate, and being connected to the front electrode;
a second semiconductor region of the second conductivity type formed in the semiconductor substrate, for extracting hole current;
a source ring provided in the intermediate region, the source ring being electrically connected to the front electrode and connected to the second semiconductor region; and
a diode or a resistor disposed between the front electrode and the source ring, the diode permitting a first current flowing from the source ring to the front electrode and blocking a second current flowing in an opposite direction, the resistor partially allowing the first current to flow from the source ring to the front electrode and inhibiting the second current to flow in the opposite direction.

5. The semiconductor device according to claim 4, wherein the diode is formed by a polysilicon layer on the semiconductor substrate via an insulating layer.

6. The semiconductor device according to claim 4, wherein
the resistor is formed by a polysilicon layer on the semiconductor substrate via an insulating layer.

7. A semiconductor device comprising:
a semiconductor substrate of a first conductivity type, the semiconductor substrate having
an active region through which a main current flows,
a terminal region surrounding a periphery of the active region in a top view of the semiconductor substrate, and
an intermediate region between the active region and the terminal region,
the semiconductor substrate having a first main surface and a second main surface opposite to each other;
a front electrode provided in the active region, on the first main surface of the semiconductor substrate;
a first semiconductor region of a second conductivity type formed in the semiconductor substrate, and being connected to the front electrode;
a second semiconductor region of the second conductivity type formed in the semiconductor substrate, for extracting hole current; and
a source ring provided in the intermediate region, the source ring being electrically connected to the front electrode and connected to the second semiconductor region, wherein
a contact resistance between the source ring and the second semiconductor region is greater than a contact resistance between the front electrode of the active region and the first semiconductor region.

8. The semiconductor device according to claim 7, wherein an average area of a region where the source ring and the second semiconductor region are in ohmic contact is smaller than an average area of a region where the front electrode in the active region and the first semiconductor region are in ohmic contact.

9. The semiconductor device according to claim 7, wherein the first semiconductor region in the active region has an impurity concentration higher than an impurity concentration of the second semiconductor region in the intermediate region.

10. The semiconductor device according to claim 1, wherein
the first semiconductor region in the active region is apart from the second semiconductor region connected to the source ring in the intermediate region.

11. The semiconductor device according to claim 4, wherein
the first semiconductor region in the active region is apart from the second semiconductor region connected to the source ring in the intermediate region.

12. The semiconductor device according to claim 7, wherein
the first semiconductor region in the active region is apart from the second semiconductor region connected to the source ring in the intermediate region.
